(19) United States
(12) Patent Application Publication
(10) Pub. No.: US 2025/0385213 A1
(43) Pub. Date: Dec. 18, 2025

(54) SEMICONDUCTOR DEVICE AND MANUFACTURING METHOD THEREFOR

(71) Applicant: FUJI ELECTRIC CO., LTD., Kawasaki-shi (JP)

(72) Inventor: Shunsuke FUKUSHIMA, Matsumoto-city (JP)

(73) Assignee: FUJI ELECTRIC CO., LTD., Kawasaki-shi (JP)

(21) Appl. No.: 19/222,472

(22) Filed: May 29, 2025

(30) Foreign Application Priority Data
Jun. 17, 2024 (JP) 2024-097140

(51) Int. Cl. H01L 23/00; H01L 25/065; H05K 1/02; H05K 1/09; H05K 3/18

(52) U.S. Cl. CPC H01L 24/29; H01L 24/32; H01L 24/83; H01L 25/0655; H05K 1/0298; H05K 1/09; H05K 3/184; H01L 2224/29109; H01L 2224/29111; H01L 2224/29113; H01L 2224/29118; H01L 2224/29139; H01L 2224/29147; H01L 2224/32227; H01L 2224/32501; H01L 2224/83192; H01L 2224/83815; H01L 2924/35121

(57) ABSTRACT

A semiconductor device, including: a conductive member, including a conductive plate that has a first chip region on a top surface thereof, the conductive plate including a metal material, and a plating film that is on the entire top surface of the conductive plate except for the first chip region; and a first semiconductor chip including a substrate that is bonded to the first chip region of the conductive plate via a first solder layer. The substrate is made of a material having a Young's modulus greater than that of silicon. The first solder layer includes a first alloy layer, which includes the metal material.

### CROSS-REFERENCE TO RELATED APPLICATION

This application is based upon and claims the benefit of priority of the prior Japanese Patent Application No. 2024-097140, filed on Jun. 17, 2024, the entire contents of which are incorporated herein by reference.

### BACKGROUND OF THE INVENTION

### 1. Field of the Invention

The embodiment discussed herein relates to a semiconductor device and a method for manufacturing the same.

### 2. Background of the Related Art

Semiconductor devices include semiconductor chips and insulated circuit boards to which the semiconductor chips are bonded, and plating is applied to circuit wiring of the insulated circuit boards (see, for example, Japanese Laid-open Patent Publication No. 2023-181607). Such plating is performed using nickel to enhance corrosion resistance (see, for example, International Publication Pamphlet No. WO 2022/244395).

In composite semiconductor devices including silicon and silicon carbide semiconductor chips, the silicon semiconductor chips plated area on an insulated circuit and the silicon carbide board, semiconductor chips are bonded to a non-plated area of the insulated circuit board using a sintered material (see, for example, Japanese Laid-open Patent Publication No. 2022-035179).

### SUMMARY OF THE INVENTION

According to an aspect, there is provided a semiconductor device including a conductive member, including: a conductive plate that has a first chip region on a top surface thereof, the conductive plate including a metal material, and a plating film that is formed on the entire top surface of the conductive plate except for the first chip region; and a first semiconductor chip including a substrate that is bonded to the first chip region of the conductive plate via a first solder layer, wherein: the substrate is made of a material having a Young's modulus greater than that of silicon, and the first solder layer includes a first alloy layer, which includes the metal material.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a perspective view of a semiconductor device according to an embodiment;

FIG. 2 is a cross-sectional view of the semiconductor device according to the embodiment;

FIG. 3 is a back view of the semiconductor device according to the embodiment;

FIG. 4 is a plan view of a semiconductor unit included in the semiconductor device according to the embodiment;

FIG. 5 is a partial plan view of the semiconductor unit included in the semiconductor device of the embodiment;

FIG. 6 is a partial cross-sectional view of the semiconductor unit included in the semiconductor device of the embodiment;

FIG. 7 is a flowchart of the method for manufacturing the semiconductor device according to the embodiment;

FIG. 8 is a partial plan view of an insulated circuit board (after a plating process) according to the embodiment;

FIG. 9 is a partial cross-sectional view of the insulated circuit board (after the plating process) according to the embodiment;

FIG. 10 is a partial plan view of the insulated circuit board (after a peeling process) according to the embodiment;

FIG. 11 is a partial cross-sectional view of the insulated circuit board (after the peeling process) according to the embodiment;

FIG. 12 is a partial plan view illustrating an application process included in the method for manufacturing the semiconductor device according to the embodiment;

FIG. 13 is a partial cross-sectional view illustrating the application process included in the method for manufacturing the semiconductor device according to the embodiment;

FIG. 14 is a partial plan view illustrating a state obtained after the application process included in the method for manufacturing the semiconductor device according to the embodiment;

FIG. 15 is a partial cross-sectional view illustrating the state obtained after the application process included in the method for manufacturing the semiconductor device according to the embodiment;

FIG. 16 is a partial plan view illustrating a state obtained after a placement process included in the method for manufacturing the semiconductor device according to the embodiment;

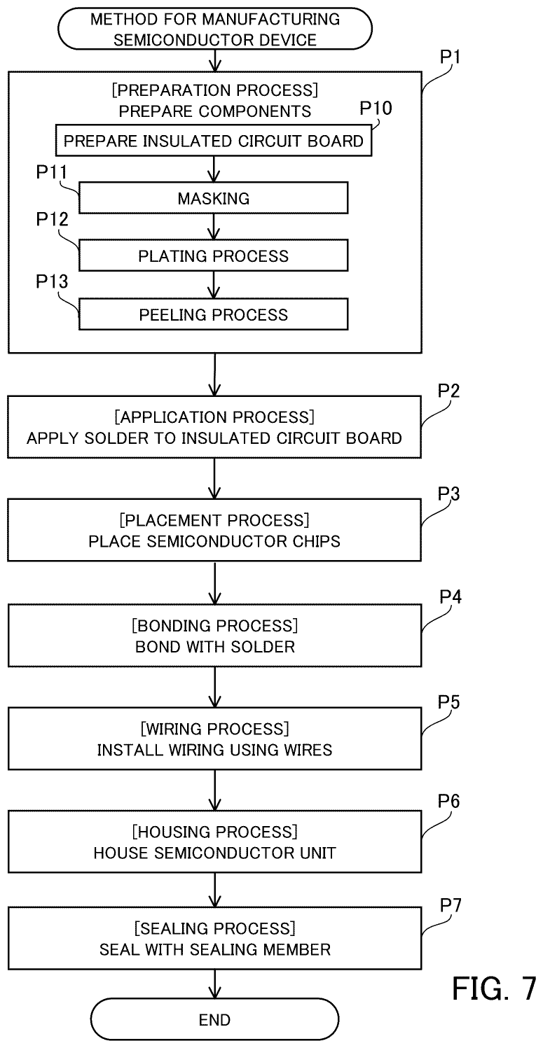

FIG. 7 is a partial cross-sectional view illustrating the state obtained after the placement process included in the method for manufacturing the semiconductor device according to the embodiment;

FIGS. 18A and 18B are schematic diagrams illustrating layer structures obtained after the placement process included in the manufacturing method of the semiconductor device according to the embodiment; and

FIGS. 19A and 19B are schematic diagrams illustrating the layer structures obtained after a bonding process included in the manufacturing method of the semiconductor device according to the embodiment.

### DETAILED DESCRIPTION OF THE INVENTION

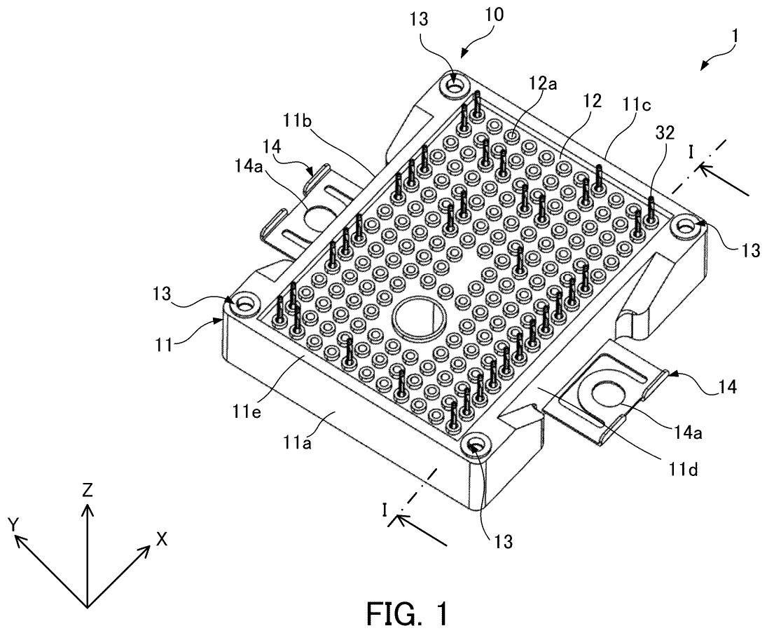

An embodiment will be described below with reference to the accompanying drawings. In the following, the terms “front surface” and “top surface” refer to the X-Y plane facing upward (in the +Z direction) in a semiconductor device 1 of FIG. 1. Similarly, the term “upper” refers to the upward direction (the +Z direction) of the semiconductor device 1 of FIG. 1. On the other hand, the terms “back surface” and “bottom surface” refer to the X-Y plane facing downward (in the −Z direction) in the semiconductor device 1 of FIG. 1. Similarly, the term “lower” refers to the downward direction (the −Z direction) of the semiconductor device 1 of FIG. 1. These terms have the same orientational relationships as described above in all the drawings if needed. The terms “front surface”, “top surface”, “upper”, “back surface”, “bottom surface”, “lower”, and “side surface” are simply expedient expressions used to specify relative positional relationships, and are not intended to limit the technical ideas of the embodiment described herein. For example, the terms “upper” and “lower” do not necessarily imply the vertical direction to the ground surface. That is, the “upper” and “lower” directions are not defined in relation to the direction of the gravitational force. In addition, the term “major component” in the following refers to a constituent having a concentration equal to 80 vol % or higher. The phrase “substantially the same” refers to where two or more things being compared have a difference of not more than ±10%. In addition, the terms “perpendicular” and “parallel” also include substantially perpendicular and substantially parallel, as appropriate, which include a margin of error of ±10° or less.

### Embodiment

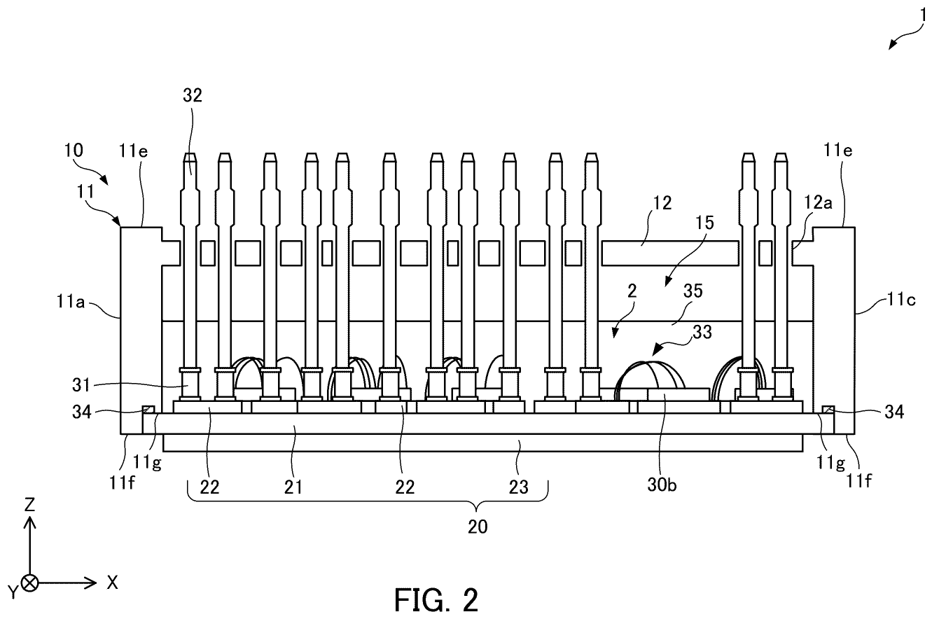

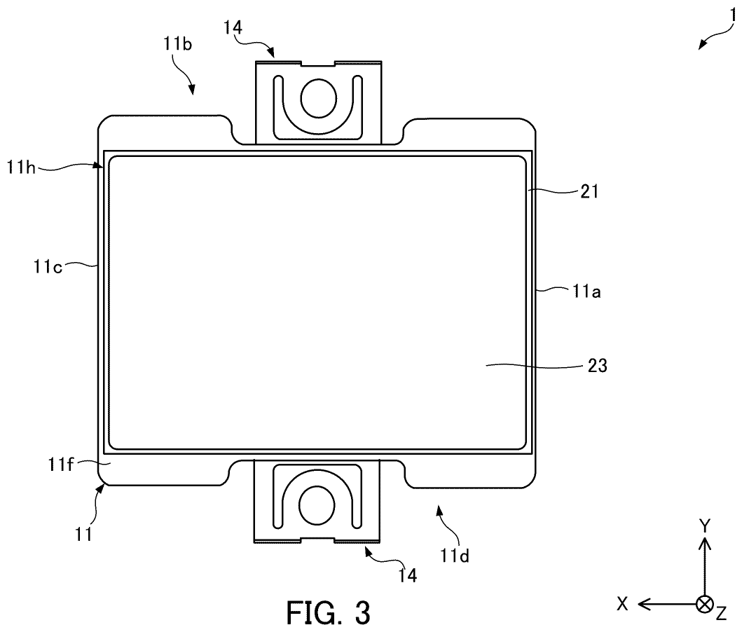

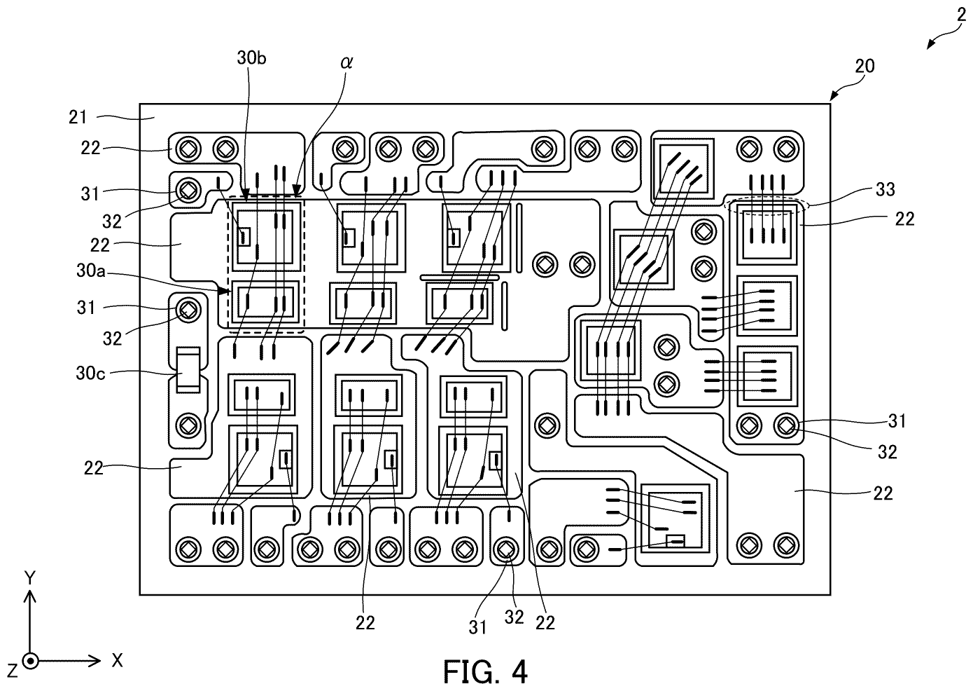

A semiconductor device according to an embodiment is described with reference to FIGS. 1 to 4. FIG. 1 is a perspective view of the semiconductor device according to the embodiment. FIG. 2 is a cross-sectional view of the semiconductor device according to the embodiment. FIG. 3 is a back view of the semiconductor device according to the embodiment. FIG. 4 is a plan view of a semiconductor unit included in the semiconductor device according to the embodiment.

The cross-sectional view of FIG. 2 is taken along a dash-dotted line I-I in FIG. 1. In the embodiment described herein, multiple conductive patterns 22, multiple first and second semiconductor chips 30a and 30b, multiple contact components 31, multiple external connection terminals 32; and multiple wires 33 are individually denoted by the same reference numerals without distinction.

The semiconductor device 1 includes a case 10 and a semiconductor unit 2 housed in the case 10. The multiple external connection terminals 32 included in the semiconductor unit 2 extend to the outside from the front surface of the case 10. The inside of the case 10 is sealed with a sealing member 35.

The case 10 has an outer frame 11 surrounding components of the semiconductor device 1 to be described later, mounting portions 14 integrally attached to the outer frame 11, and a lid portion 12 integrally attached to the outer frame 11 and covering the upper part of the outer frame 11.

The outer frame 11 has substantially rectangular box shape in plan view and includes continuous annular top surface 11e and bottom surface 11f. The top surface 11e and the bottom surface 11f are substantially parallel to each other and substantially flat and smooth. The outer frame 11 includes side walls 11a to 11d which sequentially surround a housing space 15 (see FIG. 2) on all four sides. The side walls 11a to 11d are integrally connected to each other to form a continuous annular shape in plan view. The top surface 11e and the bottom surface 11f are also integrally connected to the side walls 11a to 11d. The side walls 11a and 11c are provided along the short side direction (the ±Y direction) of the outer frame 11. The side walls 11b and 11d are provided along the long side direction (the ±X direction) of the outer frame 11. The side walls 11b and 11d are thicker in the vicinity of fastener holes 13 to be described later. In plan view, the fastener holes 13 are provided, on the top surface 11e over the side walls 11b and 11d, at positions closer to the side walls 11a and 11c.

The mounting portions 14 are each integrally formed in the center of the side wall 11b and in the center of the side wall 11d. The mounting portions 14 are substantially flat plate-shaped and are formed to be flush with the bottom surface 11f of the outer frame 11 (the side walls 11b and 11d). Each mounting portions 14 may have a mounting hole 14a. The mounting portions 14 may be made of, for example, a metal. The semiconductor device 1 is placed in a predetermined installation area, and screws are inserted through the mounting holes 14a of the mounting portions 14 to fasten the semiconductor device 1 to the installation position. In this manner, the semiconductor device 1 is fixed to the installation area.

The lid portion 12 covers the upper part of the housing space 15 and is integrally connected to each of the side walls 11a to 11d. The lid portion 12 does not need to be flush with the top surface 11e over the side walls 11a to 11d, but may be connected below the top surface 11e. The lid portion 12 may have terminal holes 12a formed in a lattice pattern. The multiple external connection terminals 32 extend vertically upward (in the +Z direction) from the outer frame 11 through the terminal holes 12a of the lid portion 12. The lid portion 12 may have an opening different from the terminal holes 12a. The opening may have a larger diameter than the terminal holes 12a. This opening may be used to introduce the sealing member 35 into the case 10 to fill therein.

The case 10 (except for the mounting portions 14) may be made of a thermoplastic resin. Examples of the thermoplastic resin include a polyphenylene sulfide resin, a polybutylene terephthalate resin, a polybutylene succinate resin, a polyamide resin, and an acrylonitrile butadiene styrene resin. The case 10 including the mounting portions 14 is formed by injection molding using the thermoplastic resin.

The semiconductor unit 2 includes an insulated circuit board 20, the semiconductor chips 30a and 30b, and the multiple external connection terminals 32. The insulated circuit board 20 includes an insulating plate 21, the multiple conductive patterns 22, and a metal plate 23. The insulating plate 21 and the metal plate 23 are rectangular in plan view. The insulating plate 21 and the metal plate 23 may have R -or C-chamfered corners. The metal plate 23 is smaller in size than the insulating plate 21 in plan view, and is thus formed inside the insulating plate 21.

The insulating plate 21 is made of a material having insulating properties and excellent thermal conductivity. The insulating plate 21 may be made of ceramics. Examples of ceramics used here include aluminum oxide, aluminum nitride, and silicon nitride.

The multiple conductive patterns 22 are formed on the front surface of the insulating plate 21. The multiple conductive patterns 22 are made of a metal having excellent conductivity. The metal used is, for example, copper, aluminum, or an alloy containing of at least one of these as a major component. Plating is applied to the surfaces of the multiple conductive patterns 22 as well as to their side surfaces. In this case, the plating material used is, for example, nickel, a nickel-phosphorus alloy, or a nickel-boron alloy. Here, the case of using nickel is taken as an example. The plated conductive patterns 22 exhibit improved corrosion resistance. Details of the multiple conductive patterns 22 are described later. Note that the multiple conductive patterns 22 illustrated here are an example, and appropriate changes may be made to the number of conductive patterns, their shapes, sizes, positions and so on, on an as-needed basis.

The metal plate 23 is formed on the back surface of the insulating plate 21. The metal plate 23 has a rectangular shape. The area of the metal plate 23 in plan view is smaller than that of the insulating plate 21, and is larger than the area of the region in which the multiple conductive patterns 22 are formed. The corners of the metal plate 23 may be R- or C-chamfered. The metal plate 23 is smaller than the size of the insulating plate 21, and is formed on the entire surface of the insulating plate 21 except for their edges. The metal plate 23 is made of a metal having excellent thermal conductivity as a major component. The metal may be, for example, copper, aluminum, or an alloy containing at least one of these. Plating may be applied to the surface of the metal plate 23. In this case, the plating material used is, for example, nickel, a nickel-phosphorus alloy, or a nickel-boron alloy. Here, the case of using nickel as the plating material is taken as an example. The plated metal plate 23 exhibits improved corrosion resistance.

As the insulated circuit board 20 having the above-described configuration, for example, a direct copper bonding (DCB) board or an active metal brazed (AMB) board may be used. A cooler (not illustrated) may be attached to the back surface of the insulated circuit board 20 (the semiconductor device 1) via a bonding member. This improves the heat dissipation of the semiconductor device 1. The cooler may be made of, for example, a metal with excellent thermal conductivity, such as aluminum, iron, silver, copper, or an alloy containing at least one of these. In addition, the cooler may be, for example, a heatsink or a water-cooled cooling device. The heatsink may have multiple fins formed thereon. As the bonding member, for example, a brazing material or a thermal interface material (TIM) may be used. The brazing material is, for example, a material having at least one of an aluminum alloy, a titanium alloy, a magnesium alloy, a zirconium alloy, and a silicon alloy as a major component. In addition, the bonding member may be a TIM. TIM is a general term for various materials such as thermally conductive grease, elastomer sheets, room temperature vulcanization (RTV) rubber, gel, and phase change materials.

The first semiconductor chips 30a may include a semiconductor substrate (substrate) made of a material having a Young's modulus greater than that of silicon. Examples of the material include silicon carbide, diamond, and aluminum nitride. The semiconductor substrate may include a substrate made of silicon carbide as a major component and gallium nitride grown on the substrate. The first semiconductor chips 30a have the semiconductor substrate made of the aforementioned material and an element structure formed on the semiconductor substrate.

The second semiconductor chips 30b are diode elements. As for the diode elements, for example, Schottky barrier diodes (SBD) or P-intrinsic-N (PiN) diodes may be used as free wheeling diodes (FWDs). The second semiconductor chips 30b have a cathode electrode as a main electrode on the back surface and an anode electrode as a main electrode on the front surface.

The second semiconductor chips 30b may include a semiconductor substrate containing silicon as a major component, and an element structure may be formed on the semiconductor substrate. The second semiconductor chips 30b each include a switching element. The switching elements are, for example, insulated gate bipolar transistors (IGBTs) or power metal-oxide-semiconductor field-effect transistors (power MOSFETs). When the second semiconductor chips 30b are IGBTs, each has a collector electrode as a main electrode on the back surface, and also has a gate electrode as a control electrode and an emitter electrode as a main electrode on the front surface. When the second semiconductor chips 30b are power MOSFETs, each has a drain electrode as a main electrode on the back surface, and also has a gate electrode as a control electrode and a source electrode as a main electrode on the front surface.

The first semiconductor chips 30a may each include a semiconductor substrate made of a material having a Young's modulus greater than that of silicon and a power MOSFET formed on the semiconductor substrate. The body diode of the power MOSFET may perform a function similar to that of a FWD of a reverse conductive insulated gate bipolar transistor (RC-IGBT). In this case, the first semiconductor chips 30a have a drain electrode as a main electrode on the back surface, and also have a gate electrode as a control electrode and a source electrode as a main electrode on the front surface. Note here that the second semiconductor chips 30b are omitted in this case, and only the first semiconductor chips 30a are used. Hereinafter, a description will be given of a case where the first semiconductor chips 30a each include a semiconductor substrate containing silicon carbide as a major component.

The first and second semiconductor chips 30a and 30b have their back surfaces bonded to the predetermined conductive patterns 22 by bonding members (not illustrated). The bonding members may be, for example, solder. Lead-free solder is used here. The lead-free solder may contain tin. Such solder contains, as a major component, at least one alloy selected from, for example, a tin-silver-copper alloy, a tin-zinc-bismuth alloy, a tin-copper alloy, and a tin-silver-indium-bismuth alloy. Further, the solder may include an additive, such as nickel, germanium, cobalt, or silicon. The inclusion of the additive increases wettability, brightness, and bond strength of the solder, which results in improved reliability.

In order for the semiconductor device 1 to realize a desired function, an electronic component 30c may be arranged on the conductive patterns 22. Depending on the function, the electronic component 30c may be, for example, a thermistor or a current sensor. The electronic component 30c may also be bonded to the conductive pattern 22 using the above-mentioned bonding members.

The external connection terminals 32 are electrically connected to the conductive patterns 22 by the contact components 31. The contact components 31 include a main body having a cylindrical through hole formed therein and a flange provided at each open end of the main body. One open end of each of the contact components 31 is bonded to a predetermined position of the multiple conductive patterns 22 provided on the front surface of the insulated circuit board 20 via a bonding member. One of the external connection terminals 32 is press-fitted into the other open end of each of the contact components 31. The contact components 31 are made of a metal having excellent electrical conductivity. The metal is, for example, copper, aluminum, silver, nickel, or an alloy containing at least one of these as a major component. Plating may be applied to the surfaces of the contact components 31 to provide improved corrosion resistance. In this case, a material used for plating is, for example, nickel, a nickel-phosphorus alloy, or a nickel-boron alloy.

The external connection terminals 32 are press-fit terminals each having a rod-shaped main body, a tapered tip formed at each end of the main body, and a thick portion formed at the upper part of the main body. The lower tip of each external connection terminal 32 is press-fitted into the contact component 31. The upper tip is later press-fitted into a printed circuit board. The main body has, for example, a polygonal columnar shape. The external connection terminals 32 are also made of a metal having excellent conductivity. The metal is, for example, copper, aluminum, nickel, or an alloy containing at least one of these as a major component. Plating may be applied to the surfaces of the external connection terminals 32 to provide improved corrosion resistance. In this case, the material used for plating is, for example, nickel, a nickel-phosphorus alloy, or a nickel-boron alloy. The external connection terminals 32 are not limited to press-fit terminals, and may be substantially straight terminals each having a main body without a thick portion.

The external connection terminals 32 may be bonded to the insulated circuit board 20 without the contact components 31. For example, the external connection terminals 32 may be bonded directly to the conductive patterns 22 of the insulated circuit board 20 by ultrasonic bonding or the like. Alternatively, the external connection terminals 32 may be bonded to the conductive patterns 22 of the insulated circuit board 20 via solder or a brazing material, for example.

In the semiconductor unit 2, a power conversion circuit is formed using the wires 33 to connect the semiconductor chips 30a and 30b, connect the conductive patterns 22 and the semiconductor chips 30a and 30b, and connect the conductive patterns 22. The wires 33 are, for example, made of gold, silver, copper, aluminum, or an alloy containing at least one of these as a major component.

The sealing member 35 includes a thermosetting resin and a filler material contained in the thermosetting resin as fillers. The thermosetting resin is, for example, an epoxy resin, a phenolic resin, or a maleimide resin. The filler material is, for example, silicon oxide, aluminum oxide, boron nitride, or aluminum nitride.

In the semiconductor device 1, the case 10 covering the components arranged on the insulated circuit board 20 is fixed by an adhesive 34 applied along the outer periphery of the insulated circuit board 20 (the insulating plate 21). Note that a step 11g is formed along an opening 11h on the inside of the bottom surface 11f of the outer frame 11 of the case 10. The cross section of the step 11g is L-shaped. The outer periphery of the insulating plate 21 of the insulated circuit board 20 is fitted into the step 11g, and the insulated circuit board 20 covers the opening 11h of the housing space 15 of the case 10 (the outer frame 11).

The sealing member 35 is filled in the housing space 15 of the case 10 and seals the front surface of the insulated circuit board 20. That is, the sealing member 35 seals the conductive patterns 22, the semiconductor chips 30a and 30b, the contact components 31, the lower parts of the external connection terminals 32, and the wires 33. There may be a gap between the front surface of the sealing member 35 and the lid portion 12.

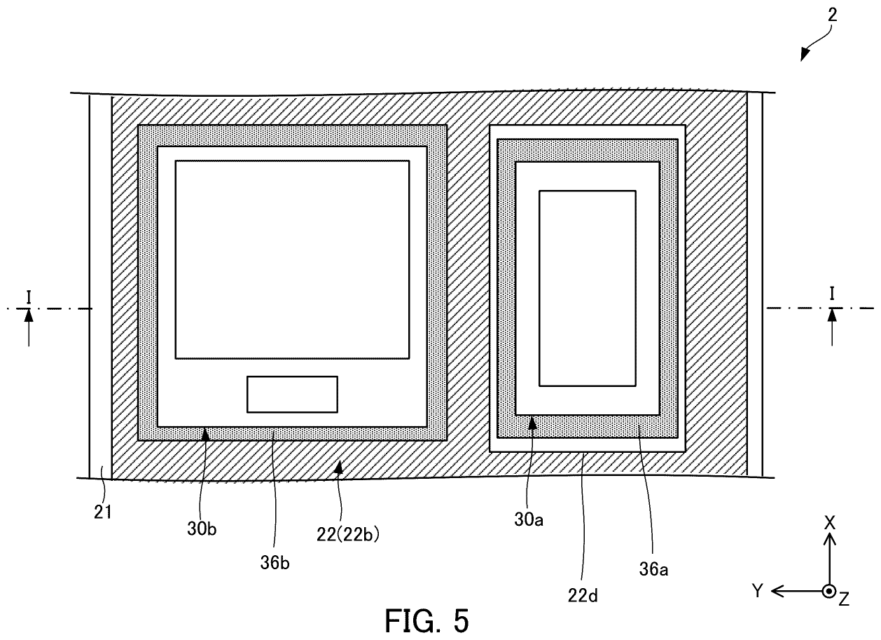

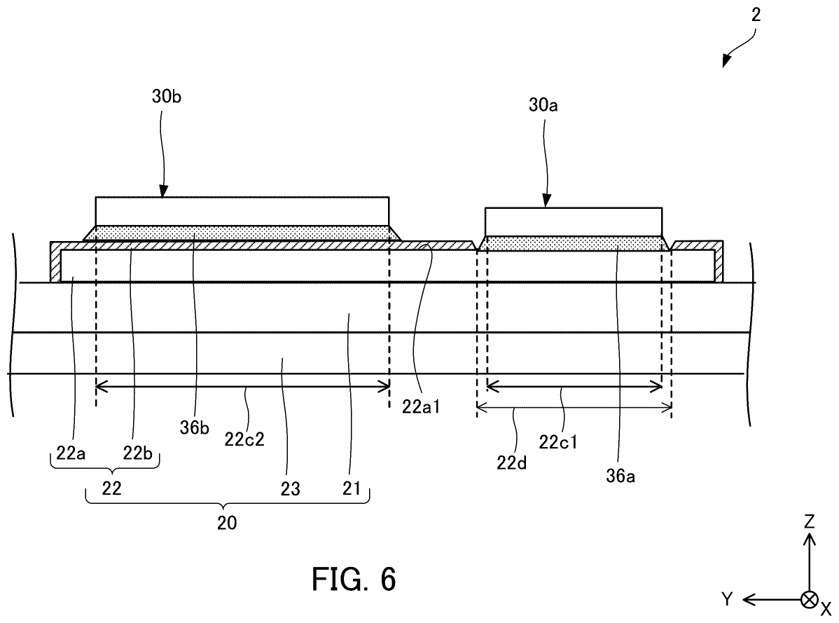

Next described are the details of the conductive patterns 22 to which the semiconductor chips 30a and 30b are bonded, with reference to FIGS. 5 and 6. FIG. 5 is a partial plan view of a semiconductor unit included in the semiconductor device of the embodiment. FIG. 6 is a partial cross-sectional view of the semiconductor unit included in the semiconductor device of the embodiment. The partial plan view of FIG. 5 corresponds to a region x in FIG. 4, surrounded by a dotted line. The partial cross-sectional view of FIG. 6 is taken along a dash-dotted line I-I in FIG. 5. Note that the following description is given on the region α in FIG. 4; however, the same applies to the conductive patterns 22 and the semiconductor chips 30a and 30b outside the region α. In the following description of the conductive patterns 22, the conductive pattern 22 of the region ⊕ is described unless otherwise specified.

As described above, the insulated circuit board 20 includes the insulating plate 21, the multiple conductive patterns 22 formed on the top surface of the insulating plate 21, and the metal plate 23 formed on the bottom surface of the insulating plate 21. In addition, the first and second semiconductor chips 30a and 30b are respectively bonded to the conductive patterns 22.

The conductive patterns 22 are plated. Therefore, the conductive patterns 22 (first and second conductive members) include a conductive plate 22a (first and second metal plates) and a plating film 22b (first and second plating films) formed on the conductive plates 22a. The plating film 22b is also formed on the side surfaces of each of the conductive patterns 22.

Note that, here, a case is described in which the first second semiconductor chips 30a and 30b are respectively bonded to a single conductive pattern 22. However, one conductive pattern 22 may be provided for each of the first and second semiconductor chips 30a and 30b. In this case, each of the two conductive patterns 22 respectively corresponding to the first and second semiconductor chips 30a and 30b may include the conductive plate 22a, and the plating film 22b may be formed on each of the conductive plates 22a.

The conductive plate 22a is patterned into a desired shape and contains copper, which is a metal with excellent conductivity. The conductive plate 22a may be made of copper or a copper alloy. The conductive plate 22a includes a top surface 22a1 on which first and second chip regions 22c1 and 22c2 are defined. To the first and second chip regions 22c1 and 22c2, the first semiconductor chips 30a and 30b, respectively, are bonded.

The plating film 22b is formed on the top surface 22a1 of the conductive plate 22a and on the side surfaces (reference numerals omitted) surrounding the top surface 22a1. Furthermore, an opening region 22d is formed in the plating film 22b. The opening region 22d has a rectangular shape in plan view, corresponding to the outer shape of the first semiconductor chip 30a (the first chip region 22c1). The entire first chip region 22c1 of the conductive plate 22a is exposed from the opening region 22d. The plating material of the plating film 22b contains nickel, as described above. Examples of the plating material include nickel, a nickel-phosphorus alloy, and a nickel-boron alloy.

The metal plate 23 is made of a metal having excellent thermal conductivity as a major component, and may be made of the same material as the conductive plate 22a. A plating film may be formed on the surface of the metal plate 23. In this embodiment, the plating film on the metal plate 23 is not illustrated.

The first semiconductor chip 30a is bonded to the first chip region 22c1 of the conductive plate 22a by a solder layer 36a (first solder layer) through the opening region 22d of the plating film 22b. The second semiconductor chip 30b is bonded to the plating film 22b of the second chip region 22c2 of the conductive plate 22a by a solder layer 36b (second solder layer). The solder layers 36a and 36b may be the same type of solder and contain tin. As described above, the solder layers 36a and 36b are made of at least one of the following alloys as a major component: a tin-silver-copper alloy, a tin-zinc-bismuth alloy, a tin-copper alloy, and a tin-silver-indium-bismuth alloy.

Next described is a method for manufacturing the above semiconductor device 1 with reference to FIG. 7. FIG. 7 is a flowchart of the method for manufacturing the semiconductor device according to the embodiment. First, a preparation process is performed to prepare components of the semiconductor device 1 (process P1). Examples of the components prepared here include the insulated circuit board 20, the first and second semiconductor chips 30a and 30b, the electronic component 30c, the contact components 31, the external connection terminals 32, and materials of the sealing member 35. Other components needed for manufacturing the semiconductor device 1 may also be prepared even if they are not listed here. In addition, devices used for manufacturing the semiconductor device 1 Examples of the manufacturing devices may be prepared. include an application device for applying solder, a bonding device for bonding wires, and a molding device for sealing with a sealing member.

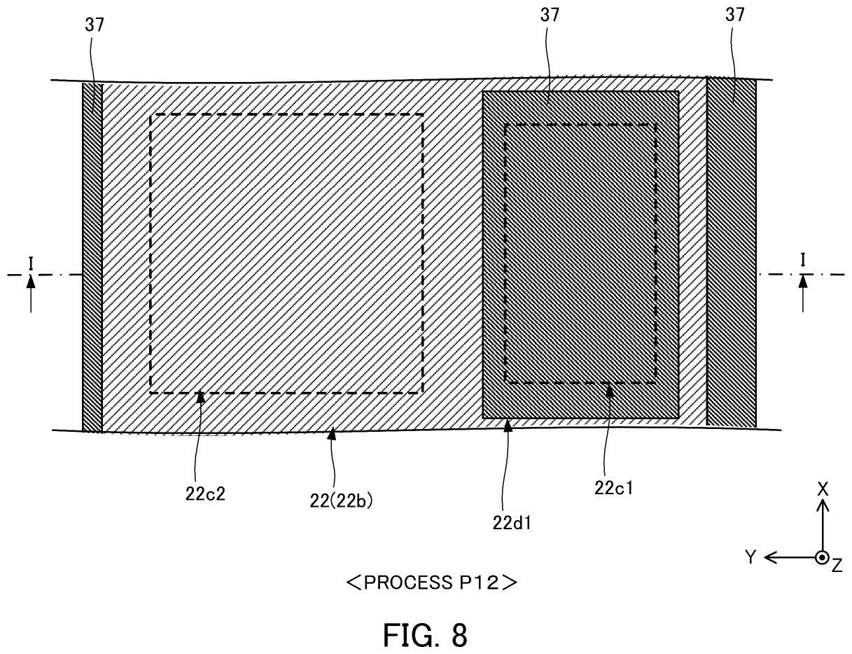

As described above, the conductive pattern 22 of the insulated circuit board 20 includes the plating film 22b. The plating process for the insulated circuit board 20 which has yet to be plated is described with reference to FIGS. 8 to 11.

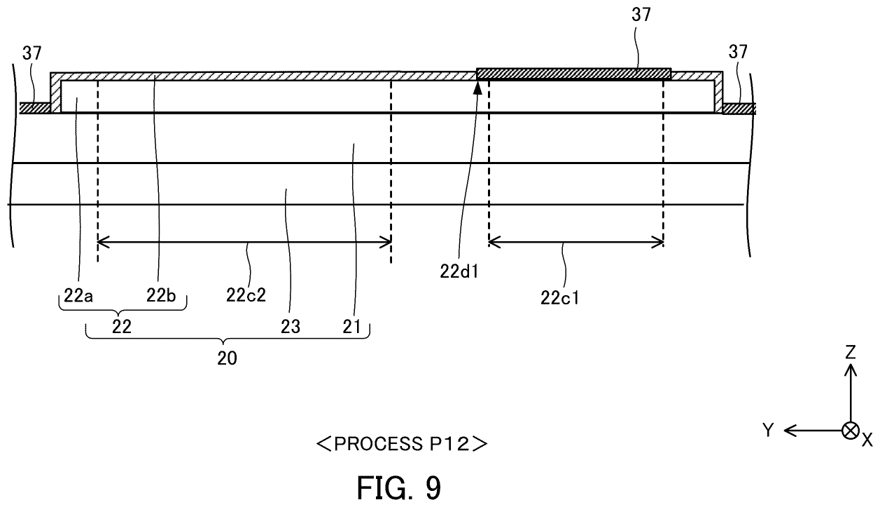

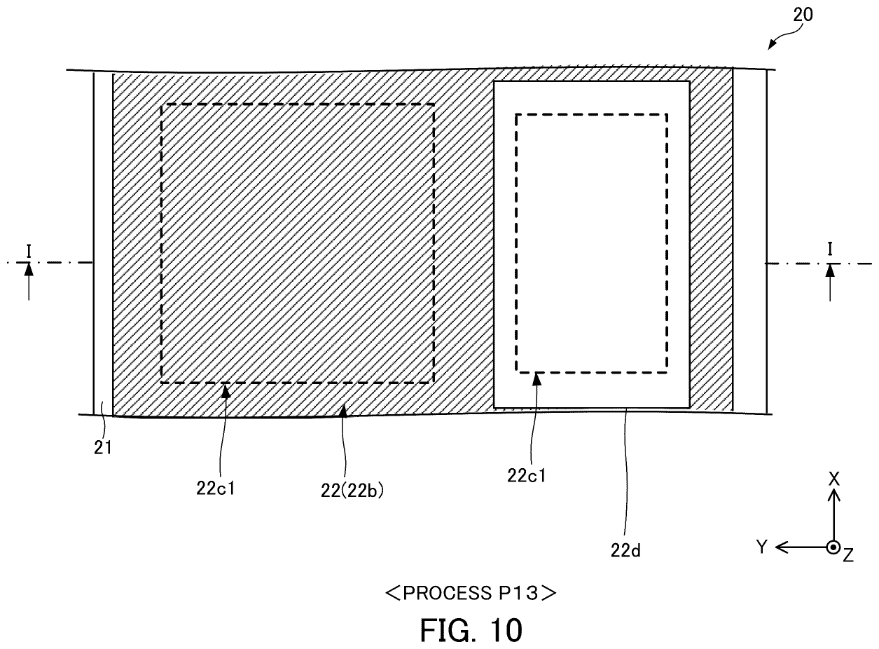

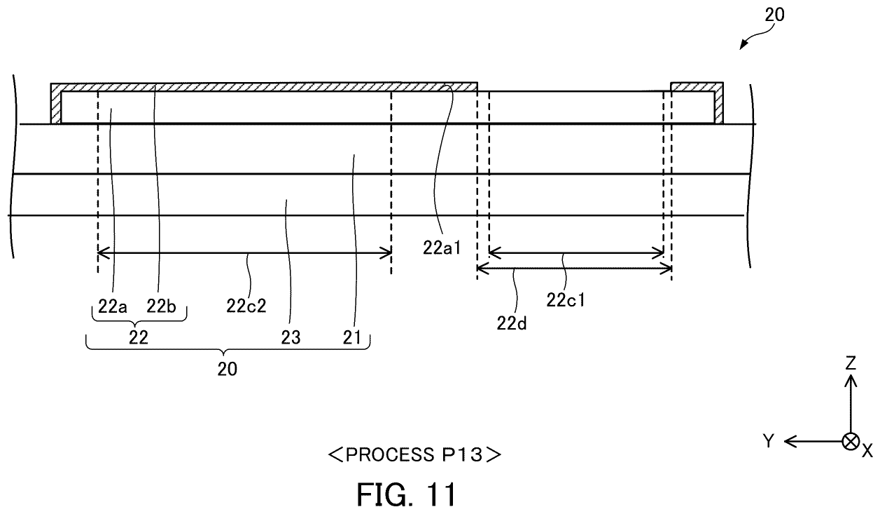

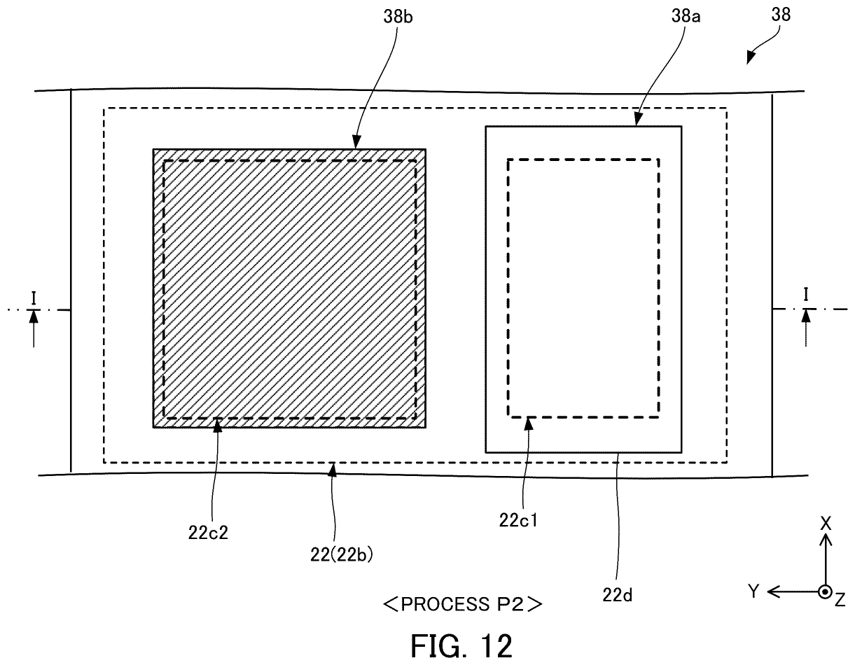

FIG. 8 is a partial plan view of an insulated circuit board (after the plating process) according to the embodiment. FIG. 9 is a partial cross-sectional view of the insulated circuit board (after the plating process) according to the embodiment. FIG. 10 is a partial plan view of the insulated circuit board (after a peeling process) according to the embodiment. FIG. 11 is a partial cross-sectional view of the insulated circuit board (after the peeling process) according to the embodiment. The cross-sectional view of FIG. 9 is taken along a dash-dotted line I-I in FIG. 8 while the cross-sectional view of FIG. 11 is taken along a dash-dotted line I-I in FIG. 10.

First, an insulated circuit board that has yet to be plated (not illustrated) is prepared (process P10). The insulated circuit board prepared here is the insulated circuit board 20 illustrated in FIGS. 4 to 6 on which the plating film 22b is not formed. That is, the insulated circuit board simply includes the insulating plate 21, the multiple conductive plates 22a formed on the top surface of the insulating plate 21, and the metal plate 23 formed on the bottom surface of the insulating plate 21. Note that FIG. 6 may be referred to for the insulating plate 21, the conductive plates 22a, and the metal plate 23.

Next, masking is performed by setting a mask on the insulated circuit board prepared in process P10 (process P11). A mask 37 (see FIGS. 8 and 9) is set on the top surface 22a1 of the conductive plate 22a included in the insulated circuit board so as to cover the first chip region 22c1. At this time, the mask 37 is also set on the top surface of the insulating plate 21 except for the conductive plate 22a. The shape of the mask 37 set on the conductive plate 22a is the same as that of the first chip region 22c1 in plan view, and the size of the mask 37 may be slightly larger than the first chip region 22c1. The mask 37 may be made of a material with a small linear expansion coefficient. The mask 37 is placed in a mask region 22d1 on the conductive plate 22a (see FIGS. 8 and 9). The mask region 22d1 corresponds to the size of the mask 37 and may be slightly larger than the first chip region 22c1.

Next, plating is performed on the conductive plate 22a of the insulated circuit board on which the mask 37 is set (process P12). The plating here may be a well-known plating process. Examples of the plating process include electroless plating and vapor deposition. In the insulated circuit board plated in this manner, the plating film 22b is formed on the area of the conductive plate 22a other than the mask 37, as illustrated in FIGS. 8 and 9.

Next, a peeling process is performed to peel off the mask 37 (process P13). The mask 37 is peeled off from the insulated circuit board illustrated in FIGS. 8 and 9. Then, as illustrated in FIGS. 10 and 11, the insulated circuit board 20 is obtained in which the plating film 22b is formed on the top surface 22a1 and the side surfaces of the conductive plate 22a except for the opening region 22d of the conductive plate 22a.

Note that the insulated circuit board 20 prepared in the preparation process of process P1 may be obtained through processes P10 to P13. The plating process for the insulated circuit board 20 described above is just an example. As long as the insulated circuit board 20 is obtained, processes other than processes P10 to P13 may be performed. For example, plating may be performed on the entire top surface 22a1 and the entire side surfaces of the conductive plate 22a, then a plated area corresponding to the first chip region 22c1 is peeled off to form the opening region 22d.

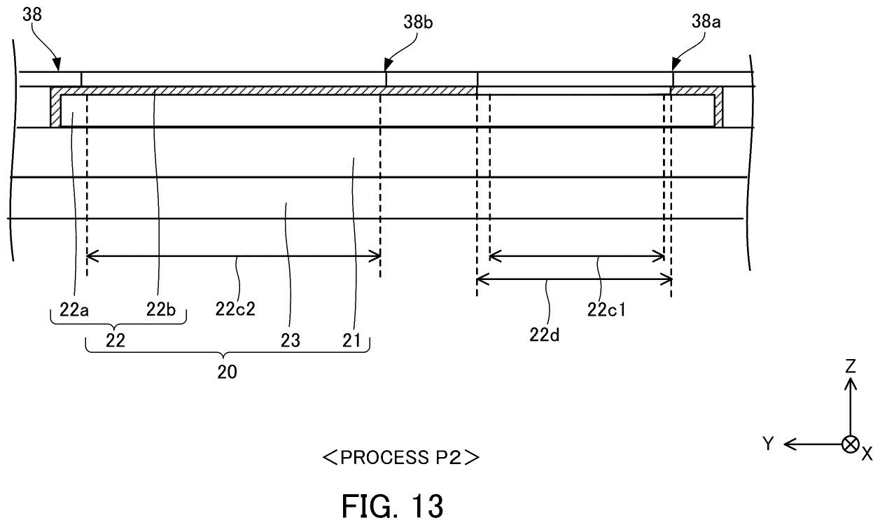

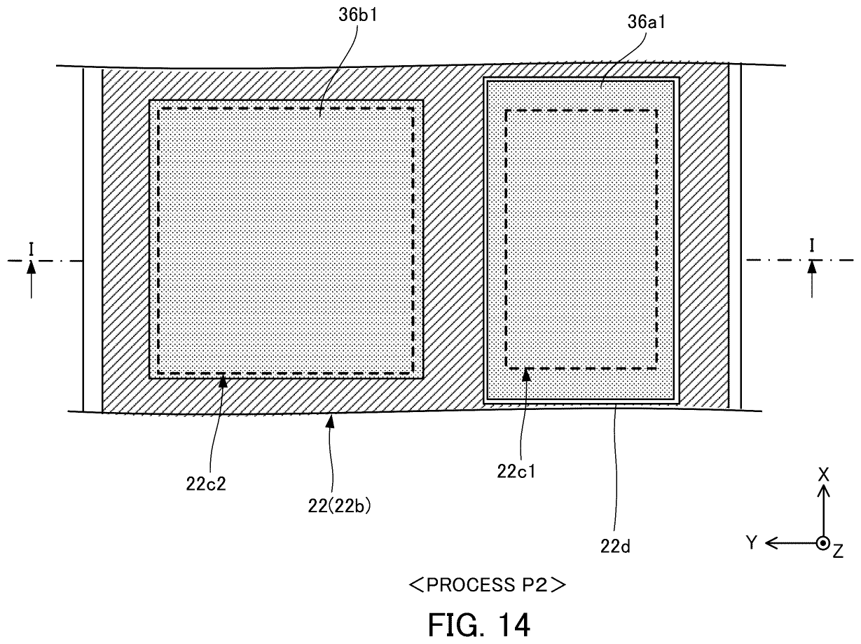

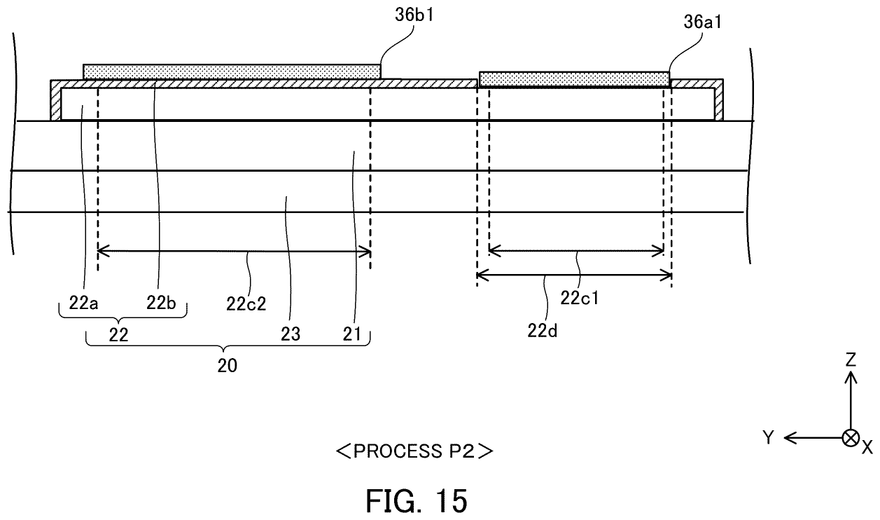

Next, an application process is performed in which a solder material is applied to the insulated circuit board 20 (process P2). The application process is described with reference to FIGS. 12 to 15. FIG. 12 is a partial plan view illustrating the application process included in the method for manufacturing the semiconductor device according to the embodiment. FIG. 13 is a partial cross-sectional view illustrating the application process included in the method for manufacturing the semiconductor device according to the embodiment. FIG. 14 is a partial plan view illustrating a state obtained after the application process included in the method for manufacturing the semiconductor device according to the embodiment. FIG. 15 is a partial cross-sectional view illustrating the state obtained after the application process included for in the method manufacturing the semiconductor device according to the embodiment.

In the application process, first, as depicted in FIGS. 12 and 13, a mask 38 is set on the conductive pattern 22 of the insulated circuit board 20. The mask 38 is flat plate-shaped, and has opening regions 38a and 38b formed therein, which are opened in correspondence with the first and second chip regions 22c1 and 22c2, respectively, when the mask 38 is set on the insulated circuit board 20. The opening regions 38a and 38b are rectangular in plan view, corresponding to the outer shapes of the first and second chip regions 22c1 and 22c2, respectively. The opening regions 38a and 38b may be slightly larger in size than the first and second chip regions 22c1 and 22c2.

The first chip region 22c1 of the conductive plate 22a is exposed from the opening region 38a of the mask 38 set on the insulated circuit board 20. In addition, the plating film 22b corresponding to the second chip region 22c2 of the conductive plate 22a is exposed from the opening region 38b of the mask 38.

Next, a solder material is applied through the opening regions 38a and 38b of the mask 38. The solder material is applied by spreading a paste solder provided on the mask 38 using a squeegee and transferring it through the opening regions 38a and 38b. Then, when the mask 38 is removed, as illustrated in FIGS. 14 and 15, a solder material 36a1 is applied to the first chip region 22c1 of the conductive plate 22a, and a solder material 36b1 is applied to the plating film 22b corresponding to the second chip region 22c2 of the conductive plate 22a.

Note that a case where a paste solder is applied as the solder materials 36a1 and 36b1 using the mask 38 and the squeegee is described as an example. The solder materials 36a1 and 36b1 to be applied (placed) are not limited to a paste solder, and may be, for example, a cream solder or sheet solder without using the mask 38 and the squeegee.

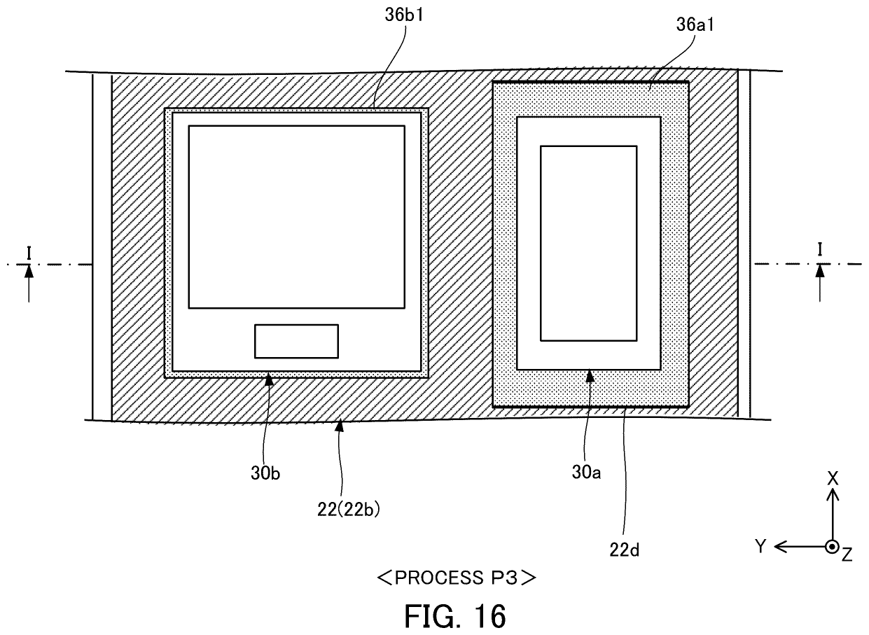

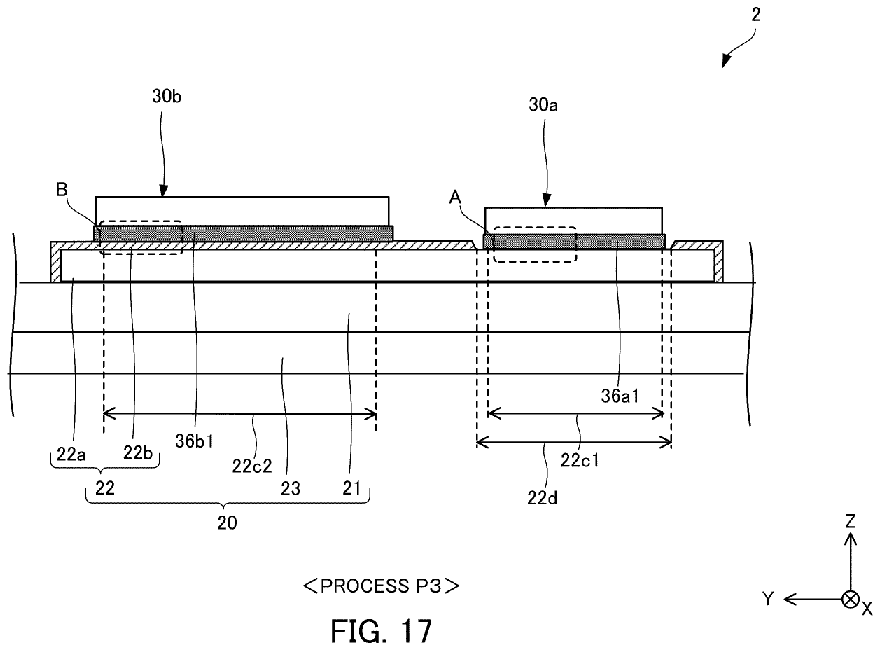

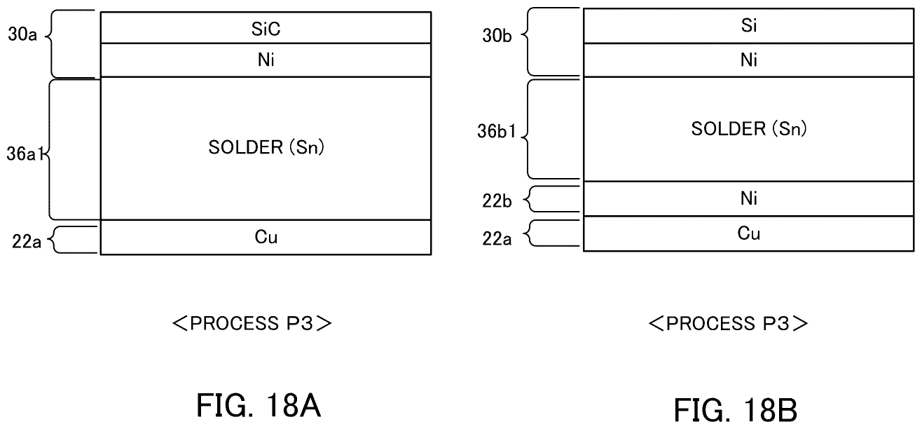

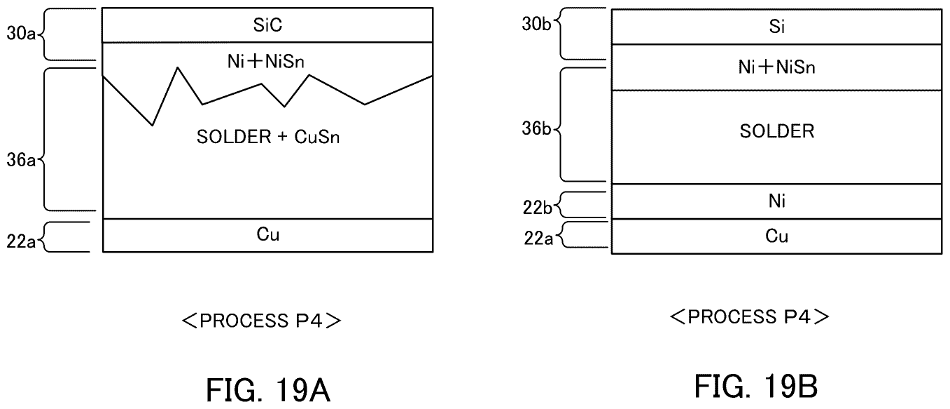

Next, a placement process is performed in which the first and second semiconductor chips 30a and 30b are placed on the solder materials 36a1 and 36b1, respectively (process P3). The placement process is described with reference to FIGS. 16 and 17. FIG. 16 is a partial plan view illustrating a state obtained after the placement process included in the method for manufacturing the semiconductor device according to the embodiment. FIG. 17 is a partial cross-sectional view illustrating the state obtained after the placement process included in the method for manufacturing the semiconductor device according to the embodiment.

After process P2, as illustrated in FIGS. 16 and 17, the first semiconductor chip 30a is placed on the solder material 36a1 applied to the first chip region 22c1 of the conductive plate 22a. Similarly, the second semiconductor chip 30b is placed on the solder material 36b1 applied to the plating film 22b corresponding to the second chip region 22c2 of the conductive plate 22a.

Layer structures in regions A and B in FIG. 17, each surrounded by a dotted line, obtained immediately after process P3 are described with reference to FIGS. 18A and 18B. FIGS. 18A and 18B are schematic diagrams illustrating the layer structures obtained after the placement process included in the manufacturing method of the semiconductor device according to the embodiment. The schematic diagrams of FIGS. 18A and 18B depict the layer structures observed in the regions A and B in FIG. 17, respectively.

In the region A, the first semiconductor chip 30a including a semiconductor substrate made of silicon carbide (SiC) as a major component is arranged on the conductive plate 22a including copper (Cu) via the solder material 36a1 including tin (Sn).

On the other hand, in the region B, the plating film 22b containing nickel (Ni) is formed on the conductive plate 22a containing copper (Cu). Then, on top of this, the second semiconductor chip 30b including a semiconductor substrate made of silicon (Si) as a major component is arranged via the solder material 36b1 containing tin (Sn).

Next, a bonding process is performed in which the first and second semiconductor chips 30a and 30b are bonded to the insulated circuit board 20 with the solder materials 36a1 and 36b1 (process P4). In the bonding process, the insulated circuit board 20 on which the first and second semiconductor chips 30a and 30b are placed via the paste solder materials 36a1 and 36b1 in process P3 is heated to melt the solder materials 36a1 and 36b1. The melted solder materials 36a1 and 36b1 are then solidified.

Herewith, as illustrated in FIGS. 5 and 6, the first semiconductor chip 30a is bonded to the first chip region 22c1 of the conductive plate 22a via the solidified solder layer 36a. Similarly, the second semiconductor chip 30b is bonded to the plating film 22b corresponding to the second chip region 22c2 of the conductive plate 22a via the solidified solder layer 36b. At this time, the contact components 31 are also bonded to the conductive pattern 22 by solder in a similar manner. The bonding of the first and second semiconductor chips 30a and 30b to the conductive pattern 22 is described later in detail.

Next, a wiring process is performed in which wiring is installed with wires on the insulated circuit board 20 to which the first and second semiconductor chips 30a and 30b are bonded (process P5). Using a bonding device, wires 33 are respectively connected, on the insulated circuit board 20, between the conductive patterns 22, between the conductive patterns 22 and the first and second semiconductor chips 30a and 30b, and between the first and second semiconductor chips 30a and 30b. In addition, in this process, the external connection terminals 32 are fitted into the contact components 31. In this manner, the semiconductor unit 2 is obtained.

Next, a housing process is performed in which the semiconductor unit 2 is housed in the case 10 (process P6). The case 10 is adhered to the outer edge of the insulated circuit board 20 with an adhesive. The front side of the insulated circuit board 20 is covered by the case 10. Finally, a sealing process is performed in which the semiconductor unit 2 in the case 10 is sealed with the sealing member 35 (process P7). The sealing member 35 is filled into the housing space 15 from, for example, an opening (not illustrated) of the lid portion 12 of the case 10, and the front side of the insulated circuit board 20 is sealed with the sealing member 35. In this manner, the semiconductor device 1 depicted in FIGS. 1 to 3 is obtained.

Here, the layer structures in the regions A and B in FIG. 7 obtained after process P4 are described with reference to FIGS. 19A and 19B. FIGS. 19A and 19B are schematic diagrams illustrating layer structures obtained after the bonding process included in the manufacturing method of the semiconductor device according to the embodiment. The schematic diagrams of FIGS. 19A and 19B depict the layer structures observed in the regions A and B in FIG. 17, respectively.

First, in the region A, copper atoms in the conductive plate 22a diffuse into the solder material 36a1 when heated. The diffused copper atoms bond with tin atoms contained in the solder layer 36a, and a copper-tin (CuSn) alloy layer (first alloy layer) is formed in the solder layer 36a. The copper-tin alloy layer is formed in a columnar shape. Therefore, in the solder layer 36a, cracks do not easily progress in the horizontal direction, which makes it difficult for the first semiconductor chip 30a to peel off from the conductive plate 22a.

On the other hand, in the region B, tin atoms and nickel atoms contained in the solder layer 36b are bonded together when heated, and as a result, a nickel-tin (NiSn) alloy layer (second alloy layer) is formed. In this case, cracks are likely to develop in the horizontal direction at the boundary between this alloy layer and the solder layer 36b. However, the second semiconductor chip 30b including a semiconductor substrate made of silicon as a major component has a Young's modulus of less than or equal to a certain value. Therefore, the second semiconductor chip 30b follows the expansion of the solder layer 36b, which reduces the progress of cracks. As a result, the second semiconductor chip 30b is less likely to peel off.

Note that the formation of the plating film 22b on the conductive plate 22a improves the corrosion resistance of the conductive plate 22a. Therefore, it may seem appropriate to form the plating film 22b on the entire surface of the conductive plate 22a of the insulated circuit board 20. In this case, the first semiconductor chip 30a including a semiconductor substrate made of silicon carbide as a major component is bonded to the plating film 22b by the solder layer 36a. Then, as in FIG. 19B, cracks are likely to develop in the horizontal direction at the boundary between the solder layer 36a and the NiSn alloy layer formed by bonding of tin atoms and nickel atoms included in the solder layer 36a. In addition, the first semiconductor chip 30a including the semiconductor substrate made of silicon carbide as a major component is not able to follow the expansion of the solder layer 36a because of having a larger Young's modulus than the semiconductor substrate made of silicon as a major component (the second semiconductor chip 30b). This results in progress of the cracks having developed at the boundary between the NiSn alloy layer and the solder layer 36a, causing the first semiconductor chip 30a to peel off.

The above-described semiconductor device 1 includes the conductive pattern 22 and the first semiconductor chip 30a. The conductive pattern 22 includes the conductive plate 22a having the first chip region 22c1 on the top surface 22a1 and the plating film 22b formed on the entire surface of the conductive plate 22a except for the first chip region 22c1. The first semiconductor chip 30a is formed on a substrate having a Young's modulus greater than that of silicon and bonded to the first chip region 22c1 of the conductive plate 22a via the solder layer 36a.

The solder layer 36a includes an alloy layer including a metal material that makes up the conductive plate 22a. At this time, the alloy layer including the metal material that makes up the conductive plate 22a is formed in a columnar shape. This causes the solder layer 36a to be less likely to develop cracks in the horizontal direction, which in turn makes it difficult for even the first semiconductor chip 30a having a Young's modulus greater than that of silicon to peel off from the conductive plate 22a. As a result, the power cycle capability of the semiconductor device 1 is improved.

The above-described semiconductor device 1 further includes the second semiconductor chip 30b formed on a silicon substrate and bonded, over the top surface 22a1 of the conductive plate 22a, to the second chip region 22c2 covered by the plating film 22b with the plating film 22b sandwiched therebetween and the solder layer 36b interposed therebetween. At this time, the solder layer 36b includes a second alloy layer including a plating material that makes up the plating film 22b. The second semiconductor chip 30b has a smaller Young's modulus than the first semiconductor chip 30a, which suppresses the second semiconductor chip 30b from peeling off. As a result, in the semiconductor device 1, it is possible to use the first and second semiconductor chips 30a and 30b made of different materials at the same time while improving the power cycle capability.

According to an aspect, it is possible to improve the power cycle capability.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a conductive member, including:
a conductive plate that has a first chip region on a top surface thereof, the conductive plate including a metal material, and
a plating film that is formed on the entire top surface of the conductive plate except for the first chip region; and
a first semiconductor chip including a substrate that is bonded to the first chip region of the conductive plate via a first solder layer, wherein:
the substrate is made of a material having a Young's modulus greater than that of silicon, and
the first solder layer includes a first alloy layer, which includes the metal material.

2. The semiconductor device according to claim 1, wherein the first solder layer includes tin.

3. The semiconductor device according to claim 2, wherein the first alloy layer includes the metal material and the tin.

4. The semiconductor device according to claim 1, wherein the metal material includes copper.

5. The semiconductor device according to claim 1, wherein the substrate is one selected from the group consisting of a silicon carbide substrate having gallium nitride grown thereon, a silicon carbide substrate, a diamond substrate, and an aluminum nitride substrate.

6. The semiconductor device according to claim 1, wherein:
the conductive plate further has a second chip region on the top surface thereof;
the plating film includes a plating material;
the semiconductor device further has a second semiconductor chip including a silicon substrate, which is bonded to the second chip region with the plating film and a second solder layer interposed therebetween; and
the second solder layer includes a second alloy layer, which includes the plating material.

7. The semiconductor device according to claim 6, wherein the second solder layer includes tin.

8. The semiconductor device according to claim 6, wherein the plating film is made of the plating material.

9. The semiconductor device according to claim 8, wherein the plating material includes nickel.

10. The semiconductor device according to claim 6, wherein:
the conductive plate is formed of a first conductive plate and a second conductive plate, the first and second chip regions being respectively on the first and second conductive plates,
the plating film includes:
a first plating film, which is formed on an entire surface of the first conductive plate except for the first chip region, and
a second plating film, which is formed on an entire surface of the second conductive plate, and
the conductive member includes:
a first conductive member, which includes the first conductive plate and the first plating film, and
a second conductive member, which includes the second conductive plate and the second plating film.

11. The semiconductor device according to claim 1, further comprising an insulated circuit board, which includes an insulating plate having the conductive member on a top surface thereof and a metal plate on a bottom surface thereof.

12. A semiconductor device manufacturing method, comprising:
preparing a conductive member, including
a conductive plate that has a first chip region and a second chip region on a top surface thereof, and
a plating film that is on the entire top surface of the conductive plate except for the first chip region,
preparing
a first semiconductor chip including a substrate that is made of a material having a Young's modulus greater than that of silicon, and
a second semiconductor chip made of silicon;
placing, on the conductive plate, a first solder material in the first chip region and a second solder material on the plating film in an area corresponding to the second chip region;
placing the first semiconductor chip on the conductive plate via the first solder material and the second semiconductor chip on the plating film in the area corresponding to the second chip region via the second solder material; and
bonding, by heating, the first semiconductor chip to the conductive plate via a first solder layer, which is obtained by melting and solidifying the first solder material, and
bonding, by heating, the second semiconductor chip to the plating film via a second solder layer, which is obtained by melting and solidifying the second solder material in the area corresponding to the second chip region.

13. The semiconductor device manufacturing method according to claim 12, wherein:
the conductive plate includes a metal material, and
the first solder layer includes a first alloy layer that includes the metal material.

14. The semiconductor device manufacturing method according to claim 12, wherein:
the plating film includes a plating material; and
the second solder layer includes a second alloy layer that includes the plating material.

15. The semiconductor device manufacturing method according to claim 12, wherein the substrate is one selected from the group consisting of a silicon carbide substrate having gallium nitride grown thereon, a silicon carbide substrate, a diamond substrate, and an aluminum nitride substrate.
